(19) United States
(12) Patent Application Publication
(10) Pub. No.: US 2025/0389783 A1
(43) Pub. Date: Dec. 25, 2025

(54) Apparatus For Diagnosing Battery and Method Thereof

(71) Applicants: HYUNDAI MOTOR COMPANY, Seoul (KR); KIA CORPORATION, Seoul (KR); IUCF-HYU (Industry-University Cooperation Foundation Hanyang University), Seoul (KR)

(72) Inventors: Hyun Jun Jang, Hwaseong-si (KR); Jong Won Lee, Seoul (KR); Si Won Kim, Seoul (KR); Woo Jae Lee, Seoul (KR)

(73) Assignees: HYUNDAI MOTOR COMPANY, Seoul (KR); KIA CORPORATION, Seoul (KR); IUCF-HYU (Industry-University Cooperation Foundation Hanyang University), Seoul (KR)

(21) Appl. No.: 18/931,995

(22) Filed: Oct. 30, 2024

(30) Foreign Application Priority Data
Jun. 24, 2024 (KR) 10-2024-0082091

(51) Int. Cl. G01R 31/392; G01R 31/36; G01R 31/3842

(52) U.S. Cl. CPC G01R 31/392; G01R 31/3648; G01R 31/3842

(57) ABSTRACT

The present disclosure relates to a battery diagnosing apparatus and a method thereof. The battery diagnosing apparatus may include a memory and a processor. The processor may be configured to identify battery current while charging a battery with designated voltage by using step voltage, and to diagnose a state of the battery based on a time section including a time point, at which charging of the battery is initiated by using the step voltage, and a time point at which the battery current corresponds to a designated data value.

### CROSS-REFERENCE TO RELATED APPLICATION

This application claims the benefit of priority to Korean Patent Application No. 10-2024-0082091, filed in the Korean Intellectual Property Office on Jun. 24, 2024, the entire contents of which are incorporated herein by reference.

### TECHNICAL FIELD

The present disclosure relates to a battery diagnosing apparatus and a method thereof, and more particularly, relates to a technology for diagnosing the state of a battery.

### BACKGROUND

As science and technology advance, electric vehicles are becoming increasingly developed and widespread. Because batteries (e.g., lithium-ion batteries) are a critical component of electric vehicles, a technology capable of safely operating these batteries is essential. The precipitation of lithium on a graphite cathode surface of a battery may significantly affect battery safety and is a major cause of performance degradation. The precipitation of lithium may lead to irreversible capacity loss in a battery and may cause accidents, such as internal short circuits and thermal runaway. Therefore, early diagnosis of lithium precipitation is helpful for safe operation of the battery. Methods of diagnosing lithium precipitation may include heat capacity analysis, resistance analysis using EIS, and dQ/dV at open-circuit voltage (OCV) following charging. However, the above-described lithium precipitation diagnosing method may not be applied to the actual environment in which the battery is operated. The analysis using EIS resistance requires expensive impedance equipment, thereby making it difficult to be mounted on a battery-powered battery management system (BMS). A capacity differential curve in an OCV state after charging may be easily distorted by noise and may not be used in the case of irreversible lithium electrodeposition. Accordingly, there is a need to research a technology for diagnosing lithium precipitation that is not distorted by noise by using step voltage in an environment where the batteries are used.

### SUMMARY

The present disclosure was made to solve the above-mentioned problems occurring in the prior art while advantages achieved by the prior art are maintained intact.

An aspect of the present disclosure provides a battery diagnosing apparatus for diagnosing battery degradation caused by lithium precipitation on a cathode, and a method thereof.

An aspect of the present disclosure provides a battery diagnosing apparatus for diagnosing a battery by performing a non-destructive diagnosing method of degradation due to lithium precipitation, based on step voltage, and a method thereof.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, a battery diagnosing apparatus may include a memory and a processor. The processor may be configured to identify battery current while charging a battery with designated voltage by using step voltage, and to diagnose a state of the battery based on a time section including a time point, at which charging of the battery is initiated by using the step voltage, and a time point at which the battery current corresponds to a designated data value.

For example, the processor may be configured to diagnose the state of the battery as an abnormal state if a difference between a reference time section and the time section exceeds a threshold range.

For example, the processor may be configured to diagnose the state of the battery as an interfacial degradation state if the difference between the reference time section and the time section includes a positive value.

For example, the processor may be configured to diagnose the state of the battery as a lithium precipitation state if the difference between the reference time section and the time section includes a negative value.

For example, the processor may be configured to normalize the battery current by using a maximum value of the battery current identified at the time point at which the charging of the battery is initiated, and to identify the time section by using profile data indicating the normalized battery current.

For example, the processor may be configured to obtain the profile data indicating the battery current decreasing while the battery is charged by using the step voltage.

For example, the processor may be configured to identify the battery current, battery voltage, and battery capacity while charging the battery with the designated voltage, by using the step voltage.

For example, the processor may be configured to charge the battery to the designated voltage based on a designated charge rate before charging the battery by using the step voltage.

For example, the processor may be configured to provide a diagnosis result of the battery based on diagnosing the state of the battery.

For example, the step voltage may exceed the designated voltage.

According to an aspect of the present disclosure, a battery diagnosing method may include identifying battery current while charging a battery with designated voltage by using step voltage, and diagnosing a state of the battery based on a time section including a time point, at which charging of the battery is initiated by using the step voltage, and a time point at which the battery current corresponds to a designated data value.

For example, the diagnosing of the state of the battery may include diagnosing the state of the battery as an abnormal state if a difference between a reference time section and the time section exceeds a threshold range.

For example, the diagnosing of the state of the battery as the abnormal state may include diagnosing the state of the battery as an interfacial degradation state if the difference between the reference time section and the time section includes a positive value.

For example, the diagnosing of the state of the battery as the abnormal state may include diagnosing the state of the battery as a lithium precipitation state if the difference between the reference time section and the time section includes a negative value.

For example, the identifying of the battery current may include normalizing the battery current by using a maximum value of the battery current identified at the time point at which the charging of the battery is initiated, and identifying the time section by using profile data indicating the normalized battery current.

For example, the identifying of the battery current may include obtaining the profile data indicating the battery current decreasing while the battery is charged by using the step voltage.

For example, the identifying of the battery current may include identifying the battery current, battery voltage, and battery capacity while charging the battery with the designated voltage, by using the step voltage.

For example, the battery diagnosing method may further include charging the battery to the designated voltage based on a designated charge rate before charging the battery by using the step voltage.

For example, the diagnosing of the state of the battery may include providing a diagnosis result of the battery based on diagnosing the state of the battery.

For example, the step voltage may exceed the designated voltage.

### BRIEF DESCRIPTION OF THE DRAWINGS

The above and other objects, features and advantages of the present disclosure will be more apparent from the following detailed description taken in conjunction with the accompanying drawings:

FIG. 1 shows an example of a block diagram associated with a battery diagnosing apparatus, according to an embodiment of the present disclosure;

FIGS. 2 and 3 show an example of a graph showing battery voltage for battery capacity, according to an embodiment of the present disclosure;

FIGS. 4 and 5 show an example of a graph indicating battery current identified by a battery diagnosing apparatus by using step voltage, according to an embodiment of the present disclosure;

FIG. 6 shows an example of a flowchart showing an operation of a battery diagnosing apparatus, according to an embodiment of the present disclosure;

FIG. 7 shows an example of a flowchart illustrating a battery diagnosing method, according to an embodiment of the present disclosure; and

FIG. 8 shows a computing system associated with a battery diagnosing apparatus or battery diagnosing method, according to an embodiment of the present disclosure.

### DETAILED DESCRIPTION

Hereinafter, some embodiments of the present disclosure will be described in detail with reference to the accompanying drawings. In adding reference numerals to components of each drawing, it should be noted that the same components include the same reference numerals, although they are indicated on another drawing. Furthermore, in describing the embodiments of the present disclosure, detailed descriptions associated with well-known functions or configurations will be omitted if they may make subject matters of the present disclosure unnecessarily obscure. In describing elements of an embodiment of the present disclosure, the terms first, second, A, B, (a), (b), and the like may be used herein. These terms are only used to distinguish one element from another element, but do not limit the corresponding elements irrespective of the nature, order, or priority of the corresponding elements. Furthermore, unless otherwise defined, all terms including technical and scientific terms used herein are to be interpreted as is customary in the art to which the present disclosure belongs. It will be understood that terms used herein should be interpreted as including a meaning that is consistent with their meaning in the context of the present disclosure and the relevant art and will not be interpreted in an idealized or overly formal sense unless expressly so defined herein.

In various embodiments of the present disclosure, the term “module” used herein may include a unit, which is implemented with hardware, software, or firmware, and may be interchangeably used with the terms “logic”, “logical block”, “part”, or “circuit”. The “module” may be a minimum unit of an integrated part or may be a minimum unit of the part for performing one or more functions or a part thereof. In an embodiment, the module may be implemented in the form of an application-specific integrated circuit (ASIC). According to various embodiments, operations executed by modules, programs, or other components may be executed by a successive method, a parallel method, or a repeated method. Alternatively, at least one or more of the operations may be executed in another order or may be omitted, or one or more operations may be added.

Various embodiments of the present disclosure may be implemented with software (e.g., a program) including one or more instructions stored in a storage medium (e.g., an internal memory or an external memory) readable by a machine (e.g., a battery diagnosing apparatus 100). For example, the processor (e.g., the processor 110) of the machine (e.g., the battery diagnosing apparatus 100) may call at least one instruction of the stored one or more instructions from a storage medium and then may execute the at least one instruction. This enables the machine to operate to perform at least one function depending on the called at least one instruction. The one or more instructions may include a code generated by a complier or a code executable by an interpreter. The machine-readable storage medium may be provided in the form of a non-transitory storage medium. Herein, ‘non-transitory’ means that the storage medium is a tangible device and does not include a signal (e.g., electromagnetic waves), and this term does not distinguish between the case where data is semipermanently stored in the storage medium and the case where the data is stored temporarily.

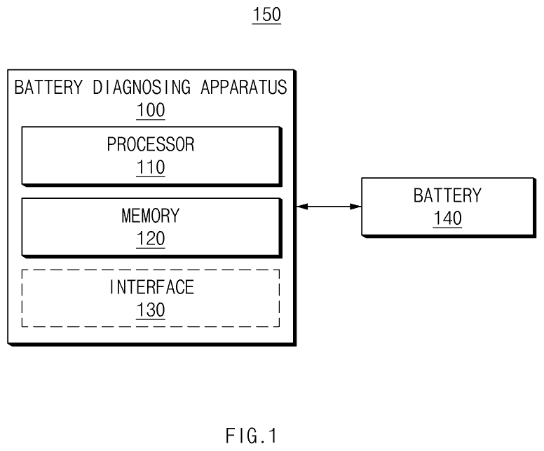

Hereinafter, embodiments of the present disclosure will be described in detail with reference to FIGS. 1 to 8.

FIG. 1 shows an example of a block diagram associated with a battery diagnosing apparatus, according to an embodiment of the present disclosure.

Referring to FIG. 1, the battery diagnosing apparatus 100 according to an embodiment of the present disclosure may be implemented inside or outside a battery 140, and some of the components included in the battery diagnosing apparatus 100 may be implemented inside or outside the battery 140. At this time, the battery diagnosing apparatus 100 may be integrated with internal control units of the battery 140 and may be implemented with a separate device so as to be coupled with control units of the battery 140 by a separate connection device. For example, the battery diagnosing apparatus 100 may further include components not shown in FIG. 1. Hereinafter, for convenience of description, the description will be made on the assumption that the battery diagnosing apparatus 100 is composed of another device external to the battery 140.

The battery diagnosing apparatus 100 according to an embodiment may include at least one of a processor 110, a memory 120, or an interface 130. The processor 110, the memory 120, and the interface 130 may be electronically and/or operably coupled with each other by an electronic component including a communication bus. Hereinafter, the fact that pieces of hardware are coupled operably may mean that a direct or indirect connection between the pieces of hardware is established by wired or wirelessly such that second hardware is controlled by first hardware among the pieces of hardware. Although shown based on different blocks, an embodiment is not limited thereto. For example, some (e.g., at least part of the processor 110, the memory 120, and a communication circuit (not shown)) of pieces of hardware in FIG. 1 may be included in a single integrated circuit, such as a system on a chip (SoC). Communication methods between components may include a bus, general purpose input and output (GPIO), serial peripheral interface (SPI), mobile industry processor interface (MIPI), or the like.

The processor 110 of the battery diagnosing apparatus 100 according to an embodiment may include a hardware component for processing data based on one or more instructions. The hardware component for processing data may include, for example, an arithmetic and logic unit (ALU), a floating point unit (FPU), a field programmable gate array (FPGA), a central processing unit (CPU), a micro controller unit (MCU), and/or an application processor (AP). The number of processors 110 may be one or more. For example, the processor 110 may include a structure of a multi-core processor including a dual core, a quad core, a hexa core, or an octa core.

The memory 120 of the battery diagnosing apparatus 100 according to an embodiment may include a hardware component for storing data and/or instructions that are to be input and/or output to the processor 110. For example, the memory 120 may include a volatile memory such as a random-access memory (RAM), and/or a non-volatile memory such as a read-only memory (ROM). For example, the volatile memory may include at least one of a dynamic RAM (DRAM), a static RAM (SRAM), a cache RAM, or a pseudo SRAM (PSRAM). For example, the non-volatile memory includes at least one of a programmable ROM (PROM), an erasable PROM (EPROM), an electrically erasable PROM (EEPROM), a flash memory, a hard disk, a compact disk, or an embedded multi-media card (eMMC). The processor 110 and/or the memory 120 may be associated with a battery diagnosing system 150 for controlling, diagnosing, and/or managing the battery.

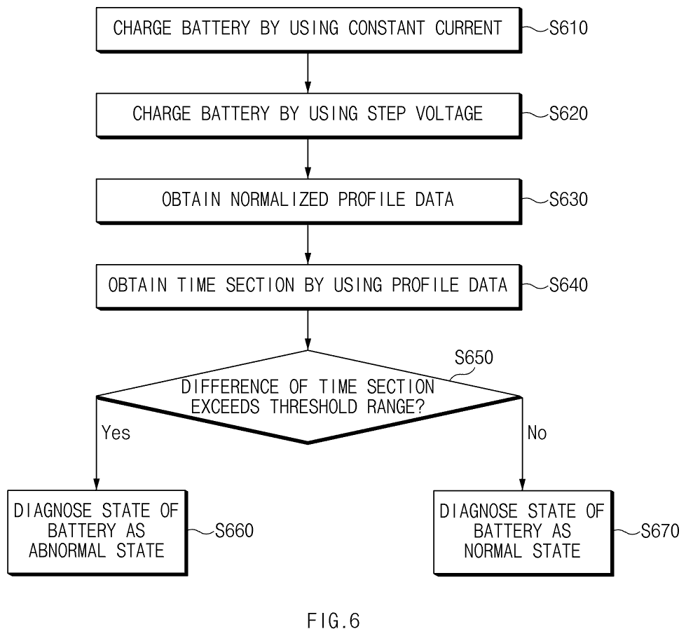

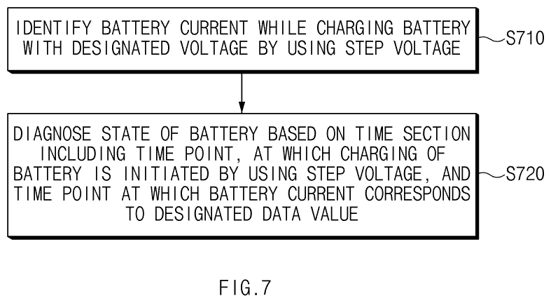

For example, one or more instructions (or instructions) indicating an arithmetic operation and/or an operation to be performed on data by the processor 110 of the battery diagnosing apparatus 100 may be stored in the memory 120 of the battery diagnosing apparatus 100 according to an embodiment. A set of one or more instructions may be referred to as a “firmware”, an “operating system”, a “process”, a “routine”, a “sub-routine”, and/or an “application”. For example, if a set of a plurality of instructions distributed in a form of an operating system, firmware, drivers, and/or applications are executed, the battery diagnosing apparatus 100 and/or the processor 110 may perform at least one of the operations of FIGS. 6 and 7.

The interface 130 of the battery diagnosing apparatus 100 according to an embodiment may be configured to generate various battery measurement values from the battery 140. To this end, the interface 130 may include a measurement device such as a voltage meter, an ammeter, and a thermometer. For example, the interface 130 may be configured to collect battery data from a battery. A test voltage or current by a charger/discharger may be applied to the battery, and the interface 130 may measure the response of the battery according to the test voltage.

The battery 140 according to an embodiment may include a battery cell, a battery module, or a battery pack. For example, the battery 140 may be composed of one or more unit cells. The battery 140 may include a capacitor or secondary battery that stores power by charging. For example, the battery 140 may include one of a lithium ion (Li-ion) battery, a lithium ion (Li-ion) polymer battery), a lead storage battery, a nickel-cadmium (NiCd) battery, or a nickel hydride (NiMH) battery. For example, the negative electrode plate of the battery 140 may include graphite and/or carbonyl methyl cellulose. For example, the positive electrode plate of the battery 140 may include lithium, nickel, manganese, cobalt, and/or polyvinylidene fluoride.

In an embodiment, the battery 140 may include a coin-shaped battery and/or a cylindrical battery. The cylindrical battery refers to a battery in which battery materials are packaged in a cylinder shape. A plurality of battery cells include a cylindrical battery. Accordingly, if lithium precipitation occurs inside the cylindrical battery during a constant voltage charging of the battery cells 11, current flowing through the battery cells may increase. This may be due to heat generation and an increase in leakage current caused by lithium precipitation inside the cylindrical battery. For example, the battery 140 may be referred to as a “diagnostic battery”, from the perspective in which the battery 140 is measured and analyzed by the battery diagnosing apparatus 100.

In an embodiment, the battery diagnosing system 150 may further include a server. The server may manage the diagnostic results of the battery diagnosing apparatus 100. The server may exchange data with the battery diagnosing apparatus 100 via wired/wireless communication. If a defect in the battery 140 is diagnosed or the lifespan of the battery 140 is predicted, the results may be delivered to the server and may be recorded in a database. For example, the server may perform operations of diagnosing the battery 140 on behalf of the battery diagnosing apparatus 100.

For example, the battery diagnosing apparatus 100 may perform operations for diagnosing the battery by executing battery management software. The server may provide updated information of the battery management software to the battery diagnosing apparatus 100.

Hereinafter, the operation of the battery diagnosing apparatus 100 may be performed by BMS associated with a battery, as well as by various devices such as a server, cloud, a charger, or a charger/discharger.

The battery diagnosing apparatus 100 according to an embodiment may identify battery current while charging the battery 140 with a designated voltage by using step voltage.

For example, the step voltage may be voltage with a different value than the designated voltage. For example, the step voltage may exceed the designated voltage. For example, the step voltage may include a value smaller than the designated voltage. For example, the step voltage may include a constant value. The operation of charging a battery using the step voltage may be referred to as “constant voltage charging”.

For example, the battery diagnosing apparatus 100 may identify the step voltage by using a diagnostic protocol for diagnosing the state of the battery 140.

For example, before charging the battery 140 by using the step voltage, the battery diagnosing apparatus 100 may charge the battery 140 up to the designated voltage based on the designated charge rate (e.g., 0.1 C-rate). The operation of charging the battery 140 to the designated voltage based on the designated charge rate may be referred to as “constant current charging”.

In an embodiment, the battery diagnosing apparatus 100 may charge (or discharge) a battery based on a charge (and discharge) cycle of the battery by using a diagnostic protocol.

For example, the battery diagnosing apparatus 100 may charge the battery 140 to the designated voltage based on the constant current charging. If the voltage of the battery is a designated voltage, the battery diagnosing apparatus 100 may temporarily stop (or pause) charging of the battery 140. The battery diagnosing apparatus 100 may stop charging the battery for a designated time (e.g., about 1 hour). For example, after the designated time, the battery diagnosing apparatus 100 may charge the battery 140 based on constant voltage charging. One charge (and discharge) cycle may include an operation of charging the battery 140 based on the constant current charging, and an operation of charging the battery 140 based on the constant voltage charging. For example, the battery diagnosing apparatus 100 may repeatedly perform the charging (and discharging) cycle.

The battery diagnosing apparatus 100 according to an embodiment may diagnose the state of the battery based on a time section including a time point, at which the charging of the battery is initiated by using the step voltage, and a time point at which battery current corresponds to a designated data value.

For example, if a difference between a reference time section and the time section exceeds a threshold range, the battery diagnosing apparatus 100 may diagnose the state of the battery 140 as an abnormal state.

The battery diagnosing apparatus 100 according to an embodiment may normalize battery current by using a maximum value of battery current identified at a time point at which charging of the battery 140 is initiated. For example, the battery diagnosing apparatus 100 may normalize the battery current by using a ratio between the battery current and the maximum value. For example, the battery diagnosing apparatus 100 may identify a time section by using profile data indicating the normalized battery current.

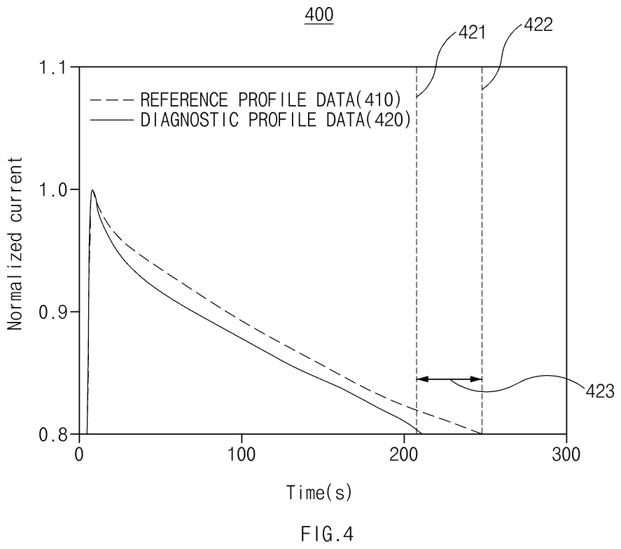

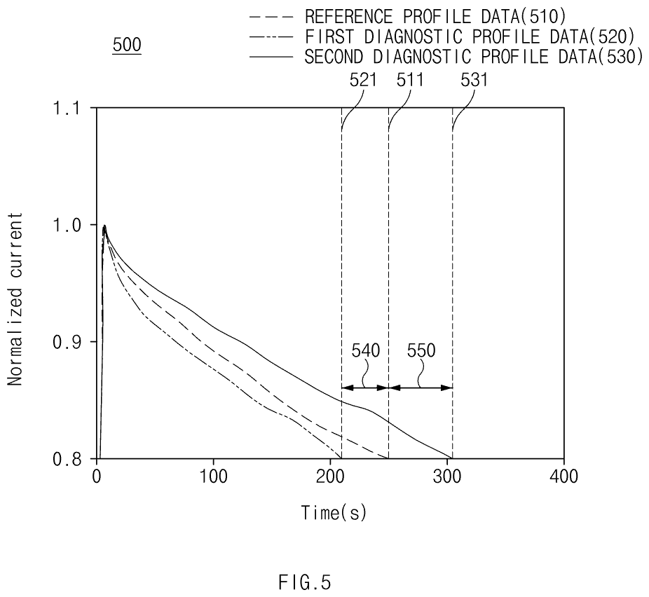

For example, the battery diagnosing apparatus 100 may obtain the profile data indicating the battery current decreasing while the battery 140 is charged by using the step voltage. For example, the profile data will be described later with reference to FIGS. 4 and 5.

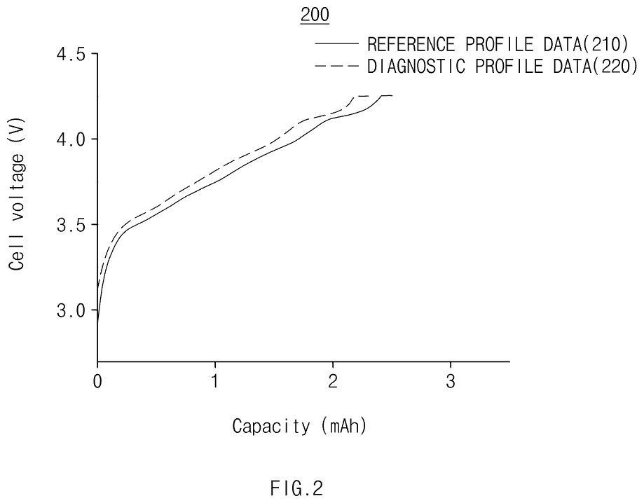

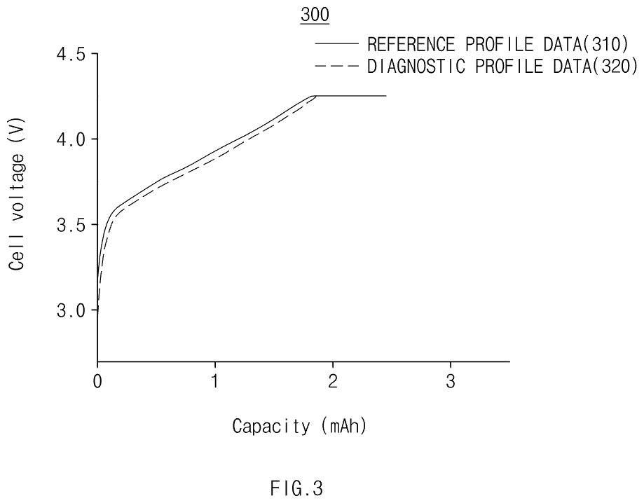

While charging a battery with the designated voltage by using the step voltage, the battery diagnosing apparatus 100 according to an embodiment may identify battery current, battery voltage, and battery capacity. For example, the battery diagnosing apparatus 100 may obtain battery data such as a graph 200 of FIG. 2 and a graph 300 of FIG. 3 by using the battery current, the battery voltage, and the battery capacity.

The battery diagnosing apparatus 100 according to an embodiment as described above may diagnose the state of the battery by applying the step voltage to the battery 140. For example, in a state where the battery 140 is used in an external device equipped with the battery 140, the battery diagnosing apparatus 100 may diagnose the state of the battery 140 by using the step voltage. For example, the battery diagnosing apparatus 100 may diagnose the state of the battery 140, thereby improving the safety of use of the battery 140.

FIGS. 2 and 3 show an example of a graph showing battery voltage for battery capacity, according to an embodiment of the present disclosure. The battery diagnosing apparatus of FIGS. 2 and 3 may refer to the battery diagnosing apparatus 100 of FIG. 1. FIGS. 2 and 3 show the graph 200 and the graph 300 showing battery voltage according to the capacity of a battery (e.g., the battery 140 in FIG. 1).

Referring to FIG. 2, in an embodiment, a battery diagnosing apparatus may identify the battery capacity and the battery voltage by repeatedly performing charging (and discharging) cycles. For example, the battery diagnosing apparatus may obtain the battery voltage for the battery capacity.

In an embodiment, the graph 200 may include a diagnostic profile data 220 indicating the battery voltage of a diagnostic battery (e.g., the battery 140 in FIG. 1) for diagnosing the state of the battery, and a reference profile data 210 indicating the battery voltage of a reference battery for diagnosing the state of the diagnostic battery.

For example, the battery diagnosing apparatus may obtain the diagnostic profile data 220 for the diagnostic battery on which a charging (and discharging) cycle using low-speed charging (e.g., 0.5 C-rate) is performed. For example, the reference profile data 210 may include data obtained by performing one charging (and discharging) cycle on the battery. For example, the diagnostic profile data 220 may include data obtained as the battery diagnosing apparatus performs two or more charging (and discharging) cycles. However, an embodiment is not limited thereto. The reference profile data 210 may include predetermined data to diagnose the state of the diagnostic battery.

Referring to FIG. 3, in an embodiment, a battery diagnosing apparatus may identify battery capacity and battery voltage by repeatedly performing charging (and discharging) cycles using high-speed charging (e.g., 6 C-rate). For example, the battery diagnosing apparatus may obtain the battery voltage for the battery capacity.

In an embodiment, the graph 300 may include a diagnostic profile data 320 indicating the battery voltage of a diagnostic battery (e.g., the battery 140 in FIG. 1) for diagnosing the state of the battery, and a reference profile data 310 indicating the battery voltage of a reference battery for diagnosing the state of the diagnostic battery.

For example, the battery diagnosing apparatus may obtain the diagnostic profile data 320 for the diagnostic battery on which a charging (and discharging) cycle using high-speed charging (e.g., 6 C-rate) is performed. For example, the reference profile data 310 may include data obtained by performing one charging (and discharging) cycle on the battery. For example, the diagnostic profile data 320 may include data obtained by performing two or more charging (and discharging) cycles. However, an embodiment is not limited thereto. The reference profile data 310 may include predetermined data to diagnose the state of the diagnostic battery.

The battery diagnosing apparatus according to an embodiment may obtain battery data including battery capacity, battery voltage, and/or battery current by performing a charging (and discharging) cycle on the battery. The battery diagnosing apparatus may obtain the battery data independently of a charge rate for charging the battery. The operation of diagnosing the state of the battery by using the battery data obtained by the battery diagnosing apparatus will be described later with reference to FIGS. 4 and 5.

FIGS. 4 and 5 show an example of a graph indicating battery current identified by a battery diagnosing apparatus by using step voltage, according to an embodiment of the present disclosure. The battery diagnosing apparatus of FIGS. 4 and 5 may refer to the battery diagnosing apparatus 100 of FIG. 1.

Referring to FIG. 4, a graph 400 may include a diagnostic profile data 420 indicating battery current obtained while a battery diagnosing apparatus (e.g., the battery diagnosing apparatus 100 in FIG. 1) charges a diagnostic battery (e.g., the battery 140 in FIG. 1) by using step voltage, and reference a profile data 410 for diagnosing the diagnostic battery.

For example, the reference profile data 410 may be associated with the reference profile data 210 of FIG. 2 and/or the profile data 310 of FIG. 3. For example, the diagnostic profile data 420 may be associated with the diagnostic profile data 220 of FIG. 2 and/or the diagnostic profile data 320 of FIG. 3.

The battery diagnosing apparatus according to an embodiment may charge a battery by using the step voltage. For example, while charging the battery by using the step voltage, the battery diagnosing apparatus may identify battery voltage, battery current, and/or battery capacity. The battery diagnosing apparatus may normalize battery current by using a maximum value of battery current identified at a time point at which charging of the battery is initiated. Profile data indicating the battery current included in the graph 400 may include data in which the battery current identified while the battery is charged is normalized.

The battery diagnosing apparatus according to an embodiment may identify a time section 421 including a time point, at which charging of the diagnostic battery is initiated by using the step voltage, and a time point, at which the battery current corresponds to a designated data value (e.g., approximately 0 or 0.3 times the maximum value).

For example, the battery diagnosing apparatus may identify a time section by using the diagnostic profile data 420 indicating normalized battery current.

For example, the battery diagnosing apparatus may identify a reference time section 422 including a time point, at which at least one value corresponding to the reference profile data 420 corresponds to the designated data value, by using the reference profile data 410.

The battery diagnosing apparatus according to an embodiment may identify a difference 423 between the time section 421 and the reference time section 422. For example, the battery diagnosing apparatus may diagnose the state of the battery by using the difference 423.

In an embodiment, if the difference 423 between the reference time section 422 and the time section 421 exceeds a threshold range (or exceeds a threshold value), the battery diagnosing apparatus may diagnose the state of the battery corresponding to the diagnostic profile data 420 as an abnormal state.

For example, the difference 423 may indicate a value obtained by subtracting a time section corresponding to the reference battery for diagnosing the diagnostic battery from a time section corresponding to the diagnostic battery. In an embodiment, the difference 423 may include at least one of a positive value or a negative value. The battery diagnosing apparatus may distinguish the state of the battery depending on whether the difference 423 is a positive or a negative value.

Referring to FIG. 5, a graph 500 may include a reference profile data 510 of the reference battery for diagnosing the state of the battery, and a first diagnostic profile data 520 and a second diagnostic profile data 530 of the diagnostic battery to be diagnosed in an abnormal state.

For example, each of the first diagnostic profile data 520 and the second diagnostic profile data 530 may correspond to the diagnostic profile data 320 of FIG. 3.

The battery diagnosing apparatus according to an embodiment may identify a difference 540 between a reference time section 511 corresponding to the reference profile data 510 and a time section 521 corresponding to the first diagnostic profile data 520.

For example, if the difference 540 between the reference time section 511 and the time section 521 exceeds a threshold range, the battery diagnosing apparatus may diagnose the state of the diagnostic battery corresponding to the first diagnostic profile data 520 as an abnormal state.

For example, if the difference 540 between the reference time section 511 and the time section 521 includes a negative value, the battery diagnosing apparatus may diagnose the state of the battery as a lithium precipitation state.

The battery diagnosing apparatus according to an embodiment may identify a difference 550 between the reference time section 511 corresponding to the reference profile data 510 and a time section 531 corresponding to the second diagnostic profile data 530.

For example, if the difference 550 between the reference time section 511 and the time section 531 exceeds the threshold range, the battery diagnosing apparatus may diagnose the state of the diagnostic battery corresponding to the second diagnostic profile data 530 as an abnormal state.

For example, if the difference 550 between the reference time section 511 and the time section 531 includes a positive value, the battery diagnosing apparatus may diagnose the state of the battery as an interfacial degradation state.

The battery diagnosing apparatus according to an embodiment may provide the battery diagnosis results based on diagnosing the state of the battery. For example, the battery diagnosing apparatus may provide the diagnostic results of the battery by transmitting the diagnostic results to a server. For example, the battery diagnosing apparatus may display the diagnosis results by using an external electronic device by transmitting the diagnosis results to the external electronic device including a display.

As described above, the battery diagnosing apparatus according to an embodiment may determine the state of the battery by using the current of the battery to be diagnosed. Because the battery diagnosing apparatus determines the state of the battery by using the current of the battery, an additional external device may not be necessary for diagnosing the battery. Accordingly, the battery diagnosing apparatus may accurately determine the state of the battery by using the current of the battery identified based on the step voltage in a usage environment where the battery is used.

FIG. 6 shows an example of a flowchart showing an operation of a battery diagnosing apparatus, according to an embodiment of the present disclosure. Hereinafter, it is assumed that the battery diagnosing apparatus 100 of FIG. 1 performs the process of FIG. 6. In addition, in a description of FIG. 6, it may be understood that an operation described as being performed by an apparatus is controlled by the processor 110 of the battery diagnosing apparatus 100. Each of the operations in FIG. 6 may be performed sequentially but is not necessarily sequentially performed. For example, the order of operations may be changed, and at least two operations may be performed in parallel.

Referring to FIG. 6, in S610, a battery diagnosing apparatus according to an embodiment may charge a battery by using constant current. For example, the battery diagnosing apparatus may charge the battery by using the constant current such that voltage of the battery becomes designated voltage (e.g., 4 V).

Referring to FIG. 6, in S620, the battery diagnosing apparatus according to an embodiment may charge the battery by using step voltage. The battery diagnosing apparatus may temporarily stop charging the battery for a designated time after performing S610.

For example, the step voltage may be voltage with a different value distinct from the designated voltage. The step voltage may include a constant voltage value.

The battery diagnosing apparatus according to an embodiment may identify battery current according to the step voltage by charging the battery by using the step voltage. For example, the battery diagnosing apparatus may charge the battery by using the step voltage until a time point where the designated data value matches the battery current.

Referring to FIG. 6, in S630, the battery diagnosing apparatus according to an embodiment may obtain normalized profile data. The profile data may indicate the battery current according to battery charging time by using the step voltage.

For example, the battery diagnosing apparatus may normalize the battery current by using the maximum value of the battery current corresponding to the time point at which the battery is charged by using the step voltage. The battery diagnosing apparatus may obtain profile data indicating the normalized battery current.

For example, the profile data indicating the battery current according to the step voltage may refer to the diagnostic profile data 420 of FIG. 4, the first diagnostic profile data 520 of FIG. 5, and/or the second diagnostic profile data 530 of FIG. 5.

Referring to FIG. 6, in S640, a battery diagnosing apparatus according to an embodiment may obtain a time section by using the profile data. The time section may include a time point, at which charging of the battery is initiated by using the step voltage, and a time point at which the battery current corresponds to the designated data value. The time section may include a section from the time point at which charging of the battery is initiated by using the step voltage to the time point at which the battery current corresponds to the designated data value.

Referring to FIG. 6, in S650, the battery diagnosing apparatus may determine whether a difference of the time section exceeds a threshold range.

For example, the battery diagnosing apparatus may identify the difference between the time section corresponding to the battery to be diagnosed and a reference time section obtained by using reference profile data for diagnosing the battery.

For example, the battery diagnosing apparatus may diagnose the state of the battery by using the difference (e.g., a difference between the reference time section and the time section) between the reference time section and the time section corresponding to the battery to be diagnosed.

If the difference of the time section does not exceed the threshold range (S650—No), in S670, the battery diagnosing apparatus according to an embodiment may diagnose the state of the battery as a normal state.

If the difference of the time section exceeds the threshold range (S650—Yes), in S660, the battery diagnosing apparatus according to an embodiment may diagnose the state of the battery as an abnormal state.

For example, if the difference of the time section includes a negative value, the battery diagnosing apparatus may diagnose the state of the battery as a lithium precipitation state. For example, if the difference 550 from the time section includes a positive value, the battery diagnosing apparatus may diagnose the state of the battery as an interfacial degradation state.

FIG. 7 shows an example of a flowchart illustrating a battery diagnosing method, according to an embodiment of the present disclosure. Hereinafter, it is assumed that the battery diagnosing apparatus 100 of FIG. 1 performs the process of FIG. 7. In addition, in a description of FIG. 7, it may be understood that an operation described as being performed by an apparatus is controlled by the processor 110 of the battery diagnosing apparatus 100. Each of the operations in FIG. 7 may be performed sequentially, but is not necessarily sequentially performed. For example, the order of operations may be changed, and at least two operations may be performed in parallel.

Referring to FIG. 7, in S710, a battery diagnosing method according to an embodiment may include an operation of identifying battery current while charging a battery with designated voltage by using step voltage.

For example, before performing operation S710, the battery diagnosing method may include an operation of obtaining a battery with the designated voltage by charging the battery by using constant current.

Referring to FIG. 7, in S720, the battery diagnosing method according to an embodiment may include an operation of diagnosing the state of the battery based on a time section including a time point, at which the charging of the battery is initiated by using the step voltage, and a time point at which battery current corresponds to a designated data value.

For example, the battery diagnosing method may include an operation of diagnosing the state of the battery by using the difference between a time section and a reference time section to diagnose the state of the battery. For example, if the difference exceeds a threshold range, the battery diagnosing method may include an operation of diagnosing the state of the battery as an abnormal state. For example, if the difference does not exceed (or is smaller than) the threshold range, the battery diagnosing method may include an operation of diagnosing the state of the battery as a normal state.

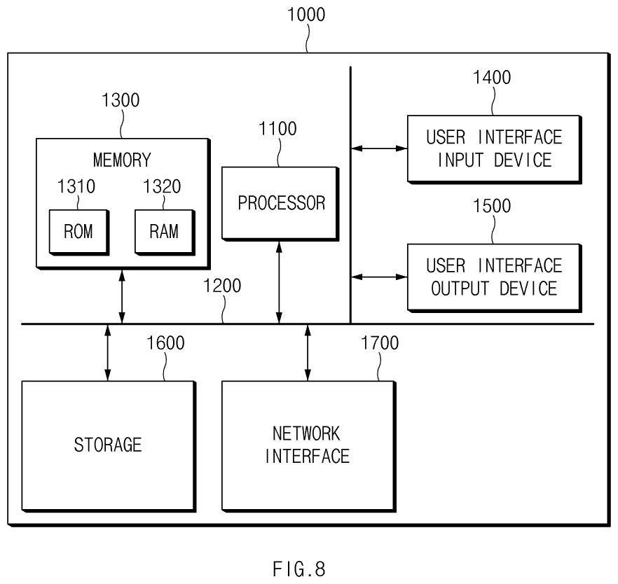

FIG. 8 shows a computing system associated with a battery diagnosing apparatus or battery diagnosing method, according to an embodiment of the present disclosure.

Referring to FIG. 8, The computing system 1000 may include at least one processor 1100, a memory 1300, a user interface input device 1400, a user interface output device 1500, a storage 1600, and a network interface 1700 connected through a system bus 1200.

The processor 1100 may be a central processing device (CPU) or a semiconductor device that processes instructions stored in the memory 1300 and/or the storage 1600. The memory 1300 and the storage 1600 may include various types of volatile or non-volatile storage media. For example, the memory 1300 may include a ROM (Read Only Memory) 1310 and a RAM (Random Access Memory) 1320.

Thus, the operations of the method or the algorithm described in connection with the embodiments disclosed herein may be embodied directly in hardware or a software module executed by the processor 1100, or in a combination thereof. The software module may reside on a storage medium (that is, the memory 1300 and/or the storage 1600) such as a RAM, a flash memory, a ROM, an EPROM, an EEPROM, a register, a hard disk, a removable disk, and a CD-ROM.

The exemplary storage medium may be coupled to the processor 1100, and the processor 1100 may read information out of the storage medium and may record information in the storage medium. Alternatively, the storage medium may be integrated with the processor 1100. The processor 1100 and the storage medium may reside in an application specific integrated circuit (ASIC). The ASIC may reside within a user terminal. In another case, the processor 1100 and the storage medium may reside in the user terminal as separate components.

The above description is merely an example of the technical idea of the present disclosure, and various modifications and modifications may be made by one skilled in the art without departing from the essential characteristic of the present disclosure.

Accordingly, embodiments of the present disclosure are intended not to limit but to explain the technical idea of the present disclosure, and the scope and spirit of the present disclosure is not limited by the above embodiments. The scope of protection of the present disclosure should be construed by the attached claims, and all equivalents thereof should be construed as being included within the scope of the present disclosure.

The present technology may diagnose battery degradation caused by lithium precipitation on a cathode.

The present technology may diagnose a battery by performing a non-destructive diagnosing method of degradation due to lithium precipitation, based on step voltage.

Besides, a variety of effects directly or indirectly understood through the present disclosure may be provided.

Hereinabove, although the present disclosure was described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

What is claimed is:

1. A battery diagnosing apparatus comprising:
a memory; and
a processor,
wherein the processor is configured to
identify battery current while charging a battery with designated voltage by using step voltage, and
diagnose a state of the battery based on a time section including a time point, at which charging of the battery is initiated by using the step voltage, and a time point at which the battery current corresponds to a designated data value.

2. The battery diagnosing apparatus of claim 1, wherein the processor is configured to
diagnose the state of the battery as an abnormal state if a difference between a reference time section and the time section exceeds a threshold range.

3. The battery diagnosing apparatus of claim 2, wherein the processor is configured to
diagnose the state of the battery as an interfacial degradation state if the difference between the reference time section and the time section includes a positive value.

4. The battery diagnosing apparatus of claim 2, wherein the processor is configured to
diagnose the state of the battery as a lithium precipitation state if the difference between the reference time section and the time section includes a negative value.

5. The battery diagnosing apparatus of claim 1, wherein the processor is configured to
normalize the battery current by using a maximum value of the battery current identified at the time point at which the charging of the battery is initiated, and
identify the time section by using profile data indicating the normalized battery current.

6. The battery diagnosing apparatus of claim 5, wherein the processor is configured to
obtain the profile data indicating the battery current decreasing while the battery is charged by using the step voltage.

7. The battery diagnosing apparatus of claim 1, wherein the processor is configured to
identify the battery current, battery voltage, and battery capacity while charging the battery with the designated voltage, by using the step voltage.

8. The battery diagnosing apparatus of claim 1, wherein the processor is configured to
charge the battery to the designated voltage based on a designated charge rate before charging the battery by using the step voltage.

9. The battery diagnosing apparatus of claim 1, wherein the processor is configured to
provide a diagnosis result of the battery based on diagnosing the state of the battery.

10. The battery diagnosing apparatus of claim 1, wherein the step voltage exceeds the designated voltage.

11. A battery diagnosing method, the method comprising:
identifying battery current while charging a battery with designated voltage by using step voltage; and
diagnosing a state of the battery based on a time section including a time point, at which charging of the battery is initiated by using the step voltage, and a time point at which the battery current corresponds to a designated data value.

12. The method of claim 11, wherein the diagnosing of the state of the battery includes
diagnosing the state of the battery as an abnormal state if a difference between a reference time section and the time section exceeds a threshold range.

13. The method of claim 12, wherein the diagnosing of the state of the battery as the abnormal state includes
diagnosing the state of the battery as an interfacial degradation state if the difference between the reference time section and the time section includes a positive value.

14. The method of claim 12, wherein the diagnosing of the state of the battery as the abnormal state includes
diagnosing the state of the battery as a lithium precipitation state if the difference between the reference time section and the time section includes a negative value.

15. The method of claim 11, wherein the identifying of the battery current includes
normalizing the battery current by using a maximum value of the battery current identified at the time point at which the charging of the battery is initiated, and
identifying the time section by using profile data indicating the normalized battery current.

16. The method of claim 15, wherein the identifying of the battery current includes
obtaining the profile data indicating the battery current decreasing while the battery is charged by using the step voltage.

17. The method of claim 11, wherein the identifying of the battery current includes
identifying the battery current, battery voltage, and battery capacity while charging the battery with the designated voltage, by using the step voltage.

18. The method of claim 11, further comprising
charging the battery to the designated voltage based on a designated charge rate before charging the battery by using the step voltage.

19. The method of claim 11, wherein the diagnosing of the state of the battery includes
providing a diagnosis result of the battery based on diagnosing the state of the battery.

20. The method of claim 11, wherein the step voltage exceeds the designated voltage.
